(19) United States
(12) Patent Application Publication
(10) Pub. No.: US 2012/0009523 A1
(43) Pub. Date: Jan. 12, 2012

(54) METHOD FOR FORMING CONTACT HOLE OF SEMICONDUCTOR DEVICE

(76) Inventors: Sung-Kwon LEE, Gyeonggi-do (KR); Cheol-Kyu Bok, Gyeonggi-do (KR); Jun-Hyeub Sun, Gyeonggi-do (KR); Shi-Young Lee, Gyeonggi-do (KR); Jong-Sik Bang, Gyeonggi-do (KR)

(21) Appl. No.: 12/896,238

(22) Filed: Oct. 1, 2010

(30) Foreign Application Priority Data
Jul. 6, 2010 (KR) 10-2010-0064952

(51) Int. Cl. G03F 7/20

(52) U.S. Cl. 430/312

(57) ABSTRACT

A method for forming a contact hole of a semiconductor device, includes forming a hard mask over an etch target layer, forming a first line pattern over the hard mask, forming a second line pattern over the hard mask and the first line pattern in a direction crossing the first line pattern, forming a mesh-type hard mask pattern by etching the hard mask using the first and second line patterns as etch barriers, and forming a contact hole by etching the etch target layer using the mesh-type hard mask pattern as an etch barrier.

### CROSS-REFERENCE TO RELATED APPLICATIONS

The present application claims priority of Korean Patent Application No. 10-2010-0064952, filed on Jul. 6, 2010, which is incorporated herein by reference in its entirety.

### BACKGROUND OF THE INVENTION

Exemplary embodiments of the present invention relate to a technology for fabricating a semiconductor device, and more particularly, to a method for forming a contact hole of a semiconductor device.

As semiconductor devices become more highly integrated, pattern linewidth becomes narrower and narrower. Herein, pattern linewidth refers to the width of parallel line-shaped structures separated by a space. Particularly, when the linewidth is approximately 30 nm, it may be difficult to perform a patterning process with a photoresist layer alone due to the limitation in the resolution of exposure equipment.

To address this concern, a method of decreasing the diameter of a contact hole by performing a reflow process on a photoresist layer or performing a Resolution Enhancement Lithography Assisted by Chemical Shrink (RELACS) process on a photoresist layer has been suggested.

The reflow process is a method of decreasing the diameter of a contact hole by forming a contact hole pattern using a photoresist layer, performing a baking process at a temperature that is not lower than a glass transition temperature, and using the characteristic that the photoresist layer expands. The RELACS process is a method of decreasing the diameter of a contact hole by forming a contact hole pattern using a photoresist layer, coating the upper portion of the photoresist layer with a RELACS material, and performing a baking process to form a new layer through a reaction between the photoresist layer and the RELACS material.

While the reflow process and the RELACS process may each decrease the diameter of a contact hole pattern, they do not reduce the pitch of the pattern. Therefore, neither the reflow process nor the RELACS process can decrease the size of a semiconductor chip itself. Also, since extreme ultraviolet (EUV) exposure technology requires expensive facilities, the use of such technology may be less economical.

Therefore, it is desirable to develop a method for forming a contact hole of a semiconductor device that may overcome the limitation of a photoresist layer pattern and achieve the goals of device integration and formation of a contact hole.

### SUMMARY OF THE INVENTION

Exemplary embodiments of the present invention are directed to a method for forming a contact hole of a semiconductor device.

In accordance with an exemplary embodiment of the present invention, a method for forming a contact hole of a semiconductor device, includes forming a hard mask over an etch target layer, forming a first line pattern over the hard mask, forming a second line pattern over the hard mask and the first line pattern in a direction crossing the first line pattern, forming a mesh-type hard mask pattern by etching the hard mask using the first and second line patterns as etch barriers, and forming a contact hole by etching the etch target layer using the mesh-type hard mask pattern as an etch barrier.

The hard mask may have a stacked structure of a first polysilicon layer and a first silicon oxynitride layer. The hard mask may further include an oxide layer, an amorphous carbon layer, or a stacked layer of an oxide layer and an amorphous carbon layer between the first polysilicon layer and the first silicon oxynitride layer.

The forming of the first line pattern may include forming a first line mask over the hard mask, forming a first sacrificial layer pattern over the first line mask, forming a first spacer pattern on sidewalls of the first sacrificial layer pattern, removing the first sacrificial layer pattern, forming the first line pattern by etching the first line mask using the first spacer pattern as an etch barrier, and removing the first spacer pattern.

The forming of the first sacrificial layer pattern may include forming a first sacrificial layer over the first line mask, forming a second silicon oxynitride layer over the first sacrificial layer, forming a first anti-reflection layer over the second silicon oxynitride layer, forming a first photoresist layer pattern, having a line type pattern, over the first anti-reflection layer, etching the first anti-reflection layer and the second silicon oxynitride layer by using the first photoresist layer pattern as an etch barrier, removing the first photoresist layer pattern and the first anti-reflection layer, and forming the first sacrificial layer pattern by etching the first sacrificial layer using the etched second silicon oxynitride layer as an etch barrier.

The forming of the first spacer pattern may include forming a spacer-forming insulation layer over the first line mask and the first sacrificial layer pattern, and etching the spacer-forming insulation layer in such a manner that the spacer-forming insulation layer remains on sidewalls of the first sacrificial layer pattern.

The first sacrificial layer pattern may have an etch selectivity with respect to the first spacer pattern. The first spacer pattern may have an etch selectivity with respect to the first line mask. The first line mask may be a polysilicon layer. The first sacrificial layer pattern may be a spin-on carbon (SOC) layer. The first spacer pattern may be an ultra low temperature oxide (ULTO) layer.

The removing of the first sacrificial layer pattern may be performed through an oxygen stripping process.

The forming of the second line pattern may include forming a second line mask over the hard mask and the first line pattern, forming a second sacrificial layer pattern over the second line mask, forming a second spacer pattern on sidewalls of the second sacrificial layer pattern, removing the second sacrificial layer pattern, and forming the second line pattern by etching the second line mask using the second spacer pattern as an etch barrier.

The second sacrificial layer pattern may have a stacked structure of a second anti-reflection layer and a second photoresist layer pattern. The forming of the second line pattern may further include forming a third silicon oxynitride layer over the second line mask, before the forming of the second sacrificial layer pattern.

The second line pattern may be formed of a material having an etch selectivity with respect to the first line pattern. The second spacer pattern may be formed of a material having an etch selectivity with respect to the second line mask.

The second line mask may be a spin-on carbon (SOC) layer. The second spacer pattern may be an ultra low temperature oxide (ULTO) layer.

In accordance with another exemplary embodiment of the present invention, a method for forming a contact hole of a semiconductor device may include forming a hard mask over an etch target layer, forming a first line mask over the hard mask, forming a first spacer pattern over the first line mask, forming a first line pattern by etching the first line mask using the first spacer pattern as an etch barrier, removing the first spacer pattern, forming a second line mask over the hard mask and the first line pattern, forming a second spacer pattern over the second line mask in a direction crossing the first line pattern, forming the second line pattern by etching the second line mask using the second spacer pattern as an etch barrier, removing the second spacer pattern, forming a mesh-type hard mask pattern by etching the hard mask, and forming a contact hole by etching the etch target layer using the mesh-type hard mask pattern as an etch barrier.

The method may further include forming a first hard mask between the hard mask and the first line mask, forming a second hard mask between the first hard mask and the first line mask, etching the second hard mask using the first and second line patterns as etch barriers, and etching the first hard mask using the etched second hard mask as an etch barrier, wherein the forming of the mesh-type hard mask pattern by etching the hard mask uses the etched first and second hard masks as etch barriers.

### BRIEF DESCRIPTION OF THE DRAWINGS

FIGS. 1A to 1P are perspective views illustrating a method for forming a contact hole of a semiconductor device in accordance with an exemplary embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

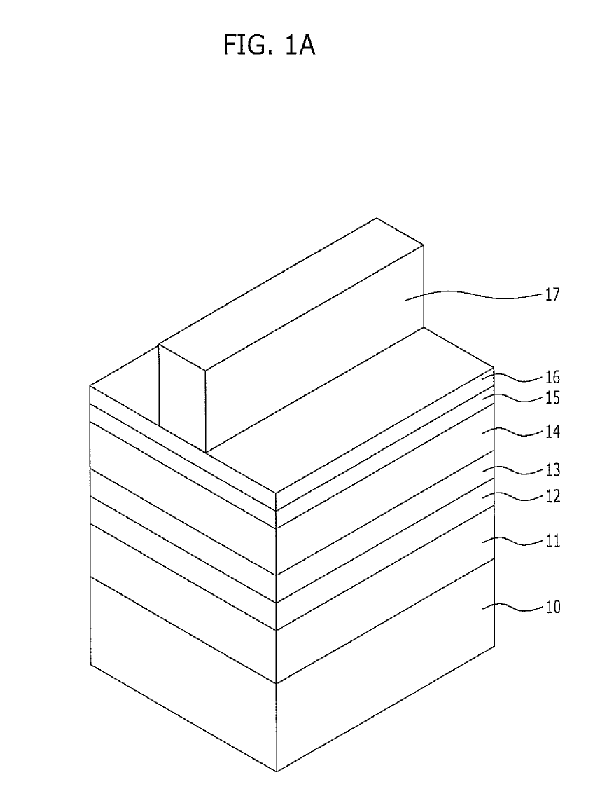

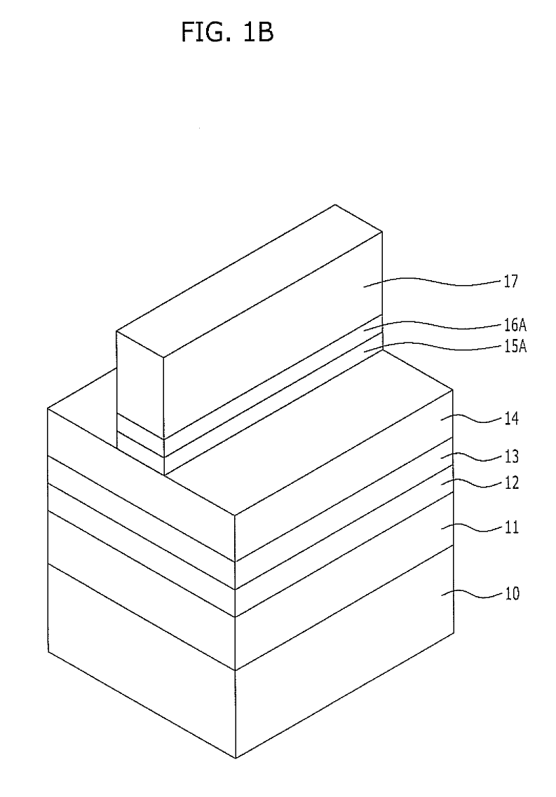

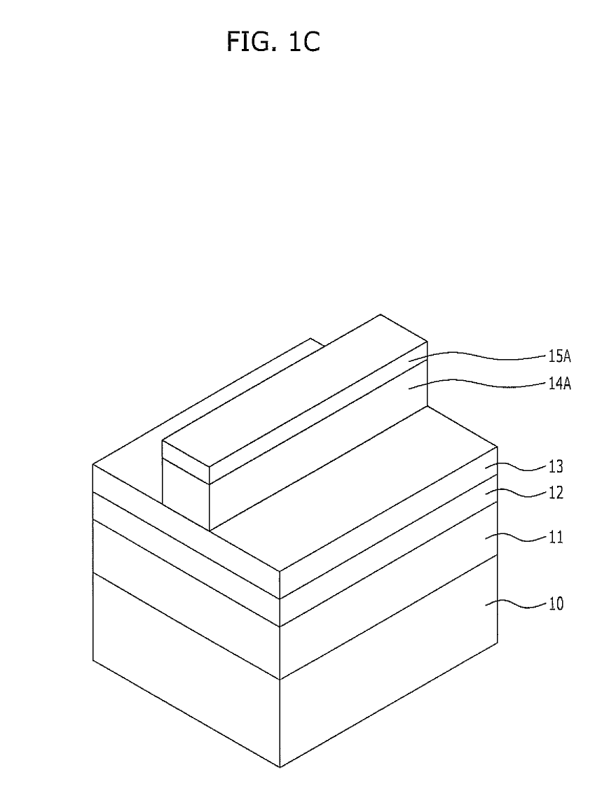

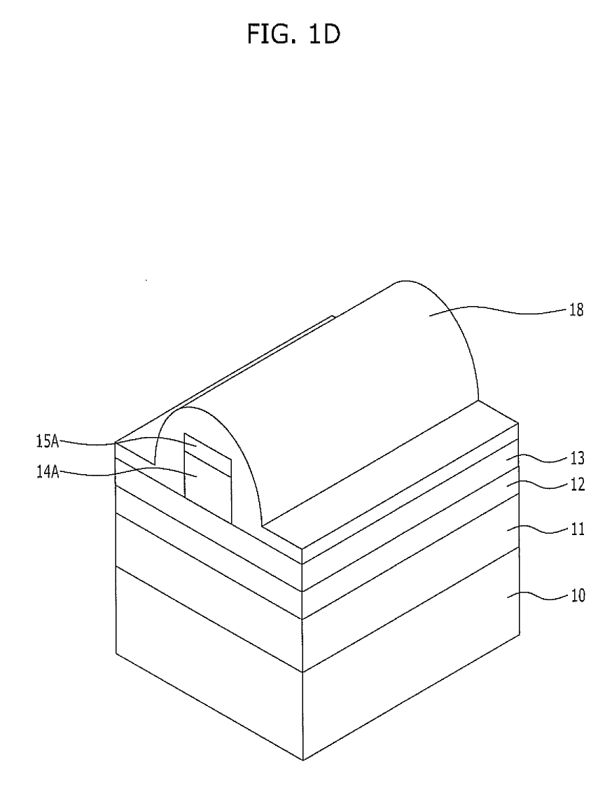

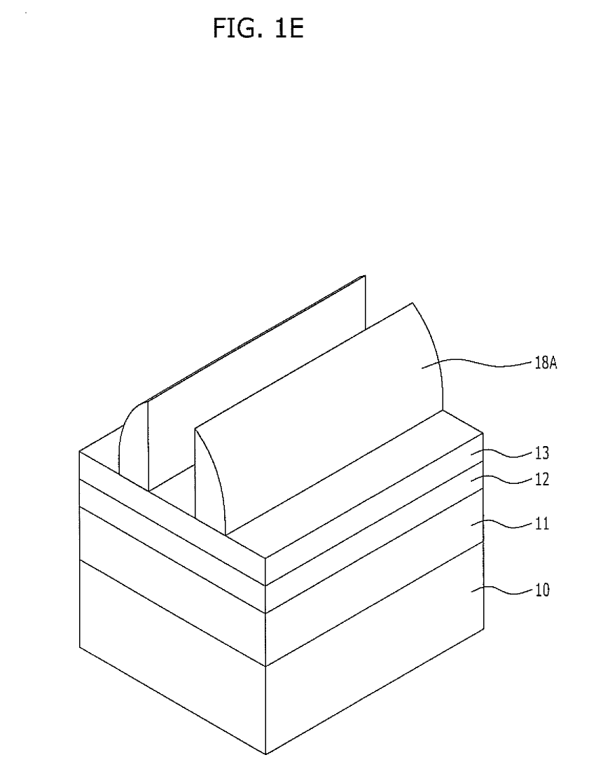

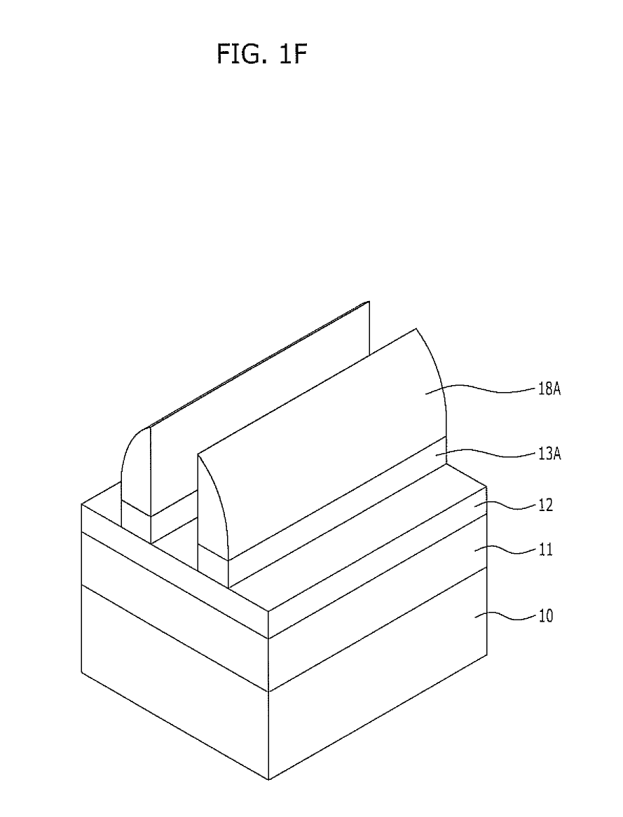

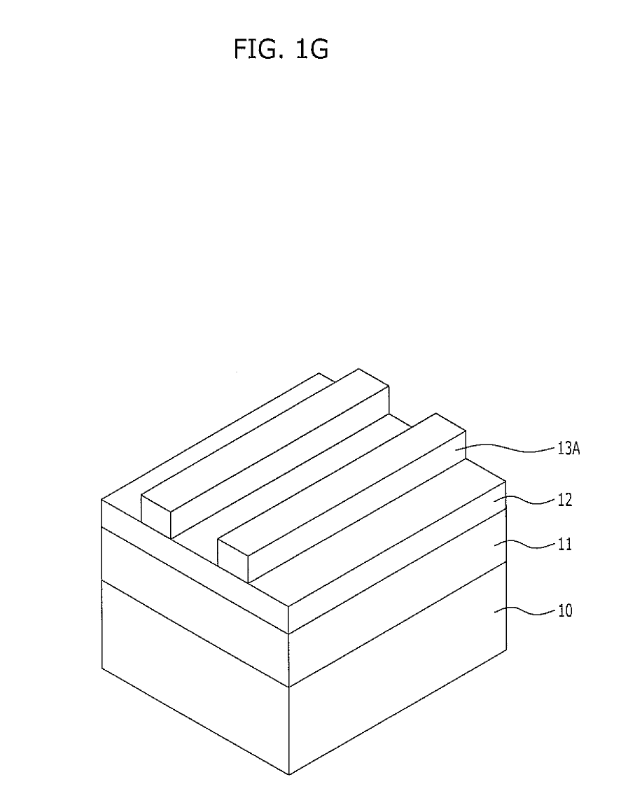

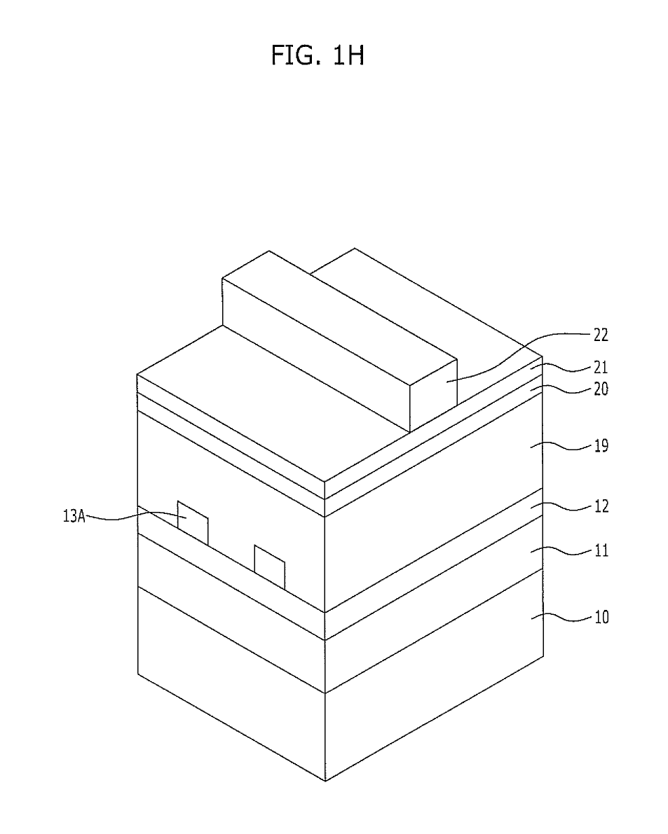

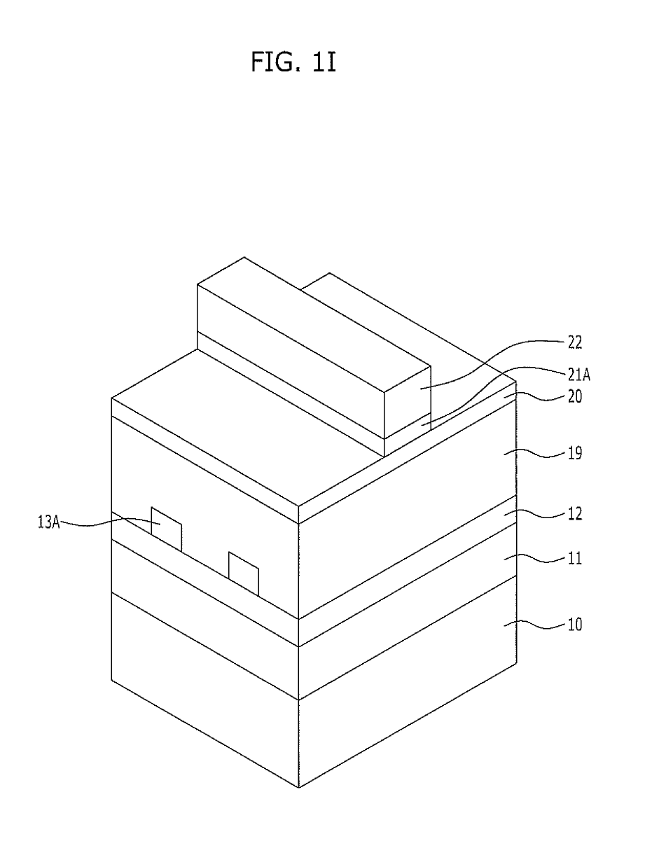

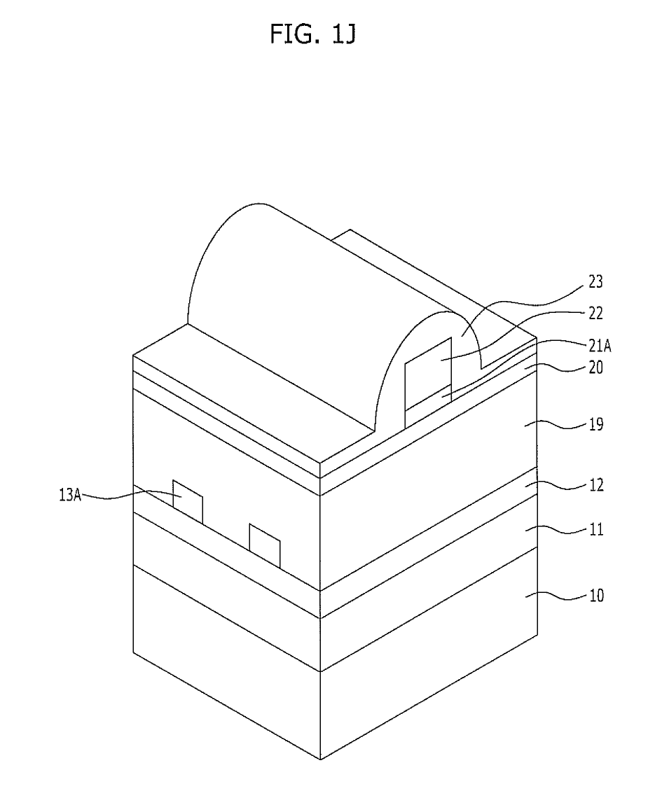

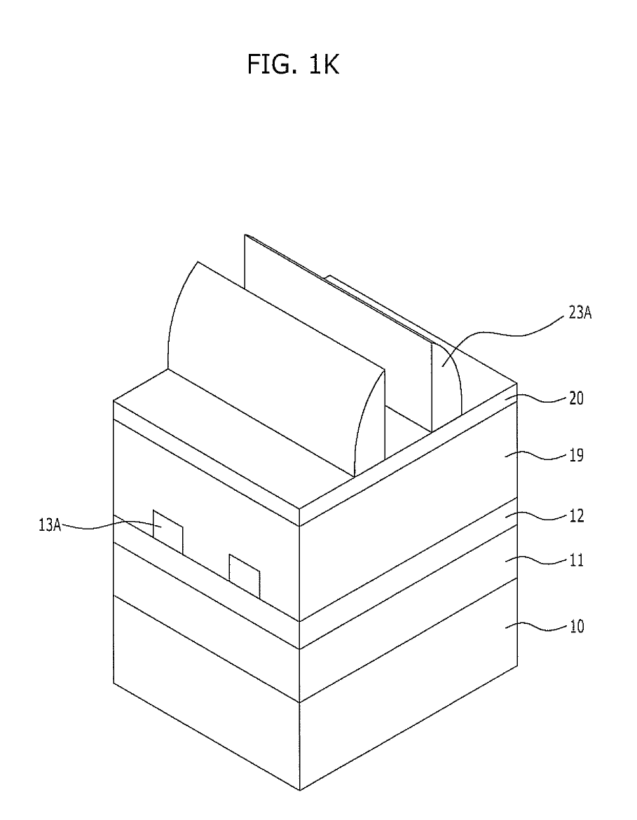

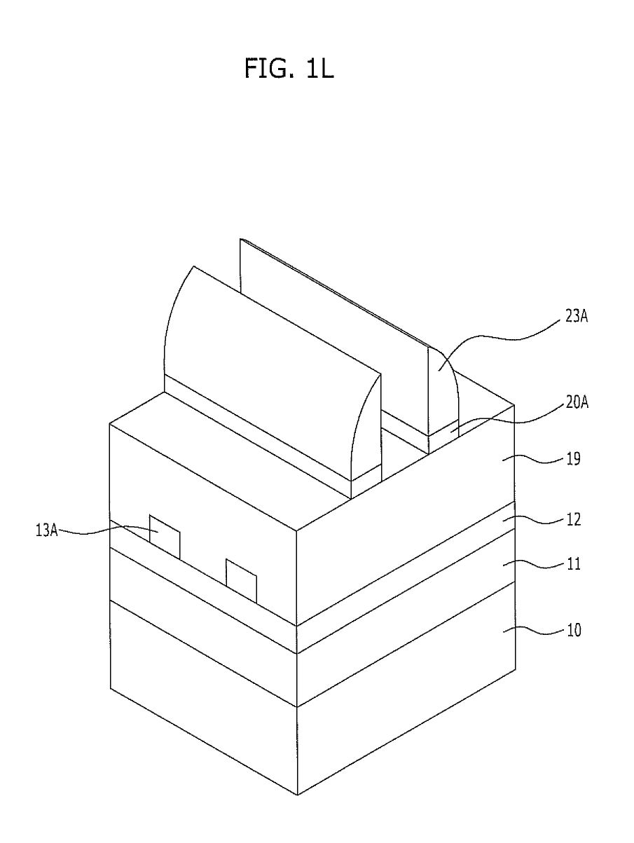

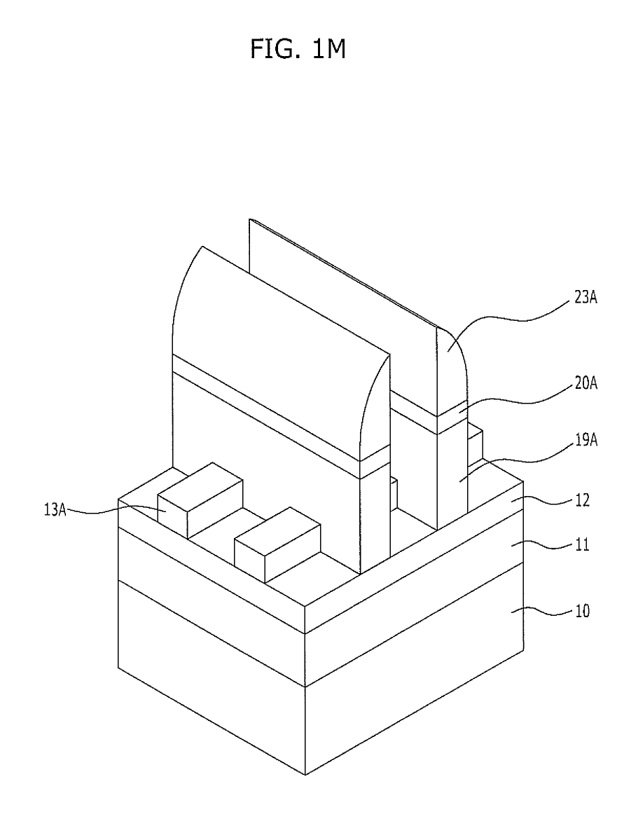

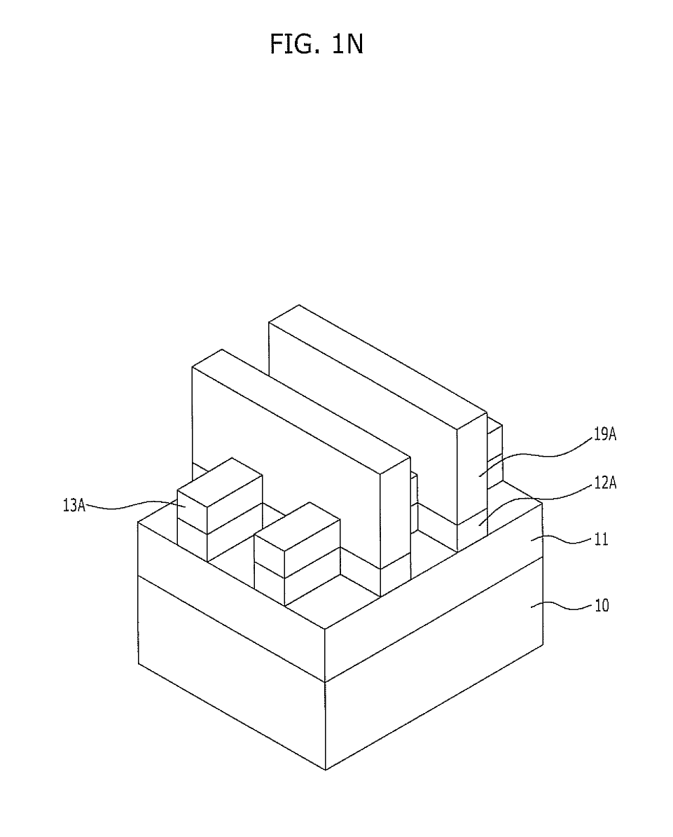

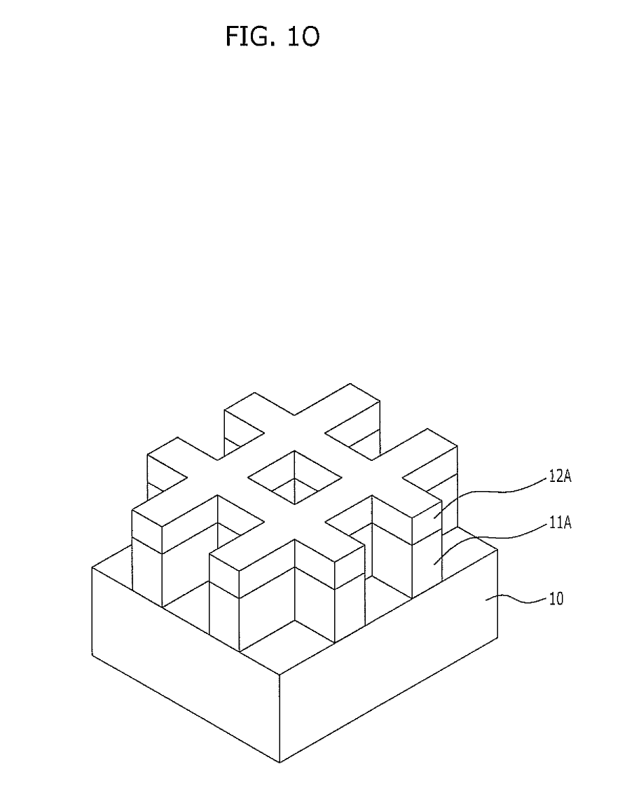

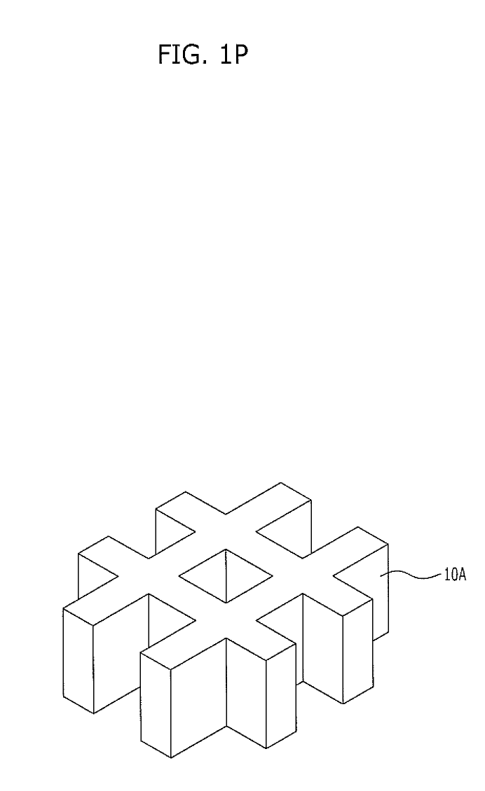

FIGS. 1A to 1P are perspective views illustrating a method for forming a contact hole of a semiconductor device in accordance with an exemplary embodiment of the present invention.

Referring to FIG. 1A, a first polysilicon layer 10, an amorphous carbon layer 11, and a first silicon oxynitride layer 12 are stacked over an etch target layer (not shown). The etch target layer (not shown) may be an insulation layer for forming a storage node. The first polysilicon layer 10 functions as a hard mask for etching the etch target layer (not shown), and the amorphous carbon layer 11 functions as a hard mask for etching the first polysilicon layer 10. Further, the first silicon oxynitride layer 12 functions as a hard mask for etching the amorphous carbon layer 11.

Ultimately, the contact hole is formed by etching the etch target layer (not shown) using a mesh-type hard mask made from at least the polysilicon layer 10.

Returning to FIG. 1A, a second polysilicon layer 13, a first spin-on carbon (SOC) layer 14, a second silicon oxynitride layer 15, and a first anti-reflection layer 16 are stacked over the first silicon oxynitride layer 12. The second polysilicon layer 13 is a layer where a first line pattern is to be formed during a subsequent process. The first SOC layer 14 functions as a hard mask for etching the second polysilicon layer 13 and it also functions as a sacrificial layer when a first spacer pattern is subsequently formed. The second silicon oxynitride layer 15 functions as a hard mask for etching the first SOC layer 14, and the first anti-reflection layer 16 functions as a layer for preventing reflection during a subsequent exposure process for forming a first photoresist layer pattern 17. The second silicon oxynitride layer 15 may be used as an anti-reflection layer along with the first anti-reflection layer 16.

Subsequently, the first photoresist layer pattern 17 is formed over the first anti-reflection layer 16. The first photoresist layer pattern 17 is a line type pattern, which is characterized by parallel line-shaped structures separated by a space. The space between patterns may be controlled in consideration of a spacer pattern which is formed subsequently.

Referring to FIG. 1B, the first anti-reflection layer 16 (refer to FIG. 1A) and the second silicon oxynitride layer 15 (refer to FIG. 1A) are etched using the first photoresist layer pattern 17 as an etch barrier.

The etched first anti-reflection layer 16 (refer to FIG. 1A) and the etched second silicon oxynitride layer 15 (refer to FIG. 1A) are referred to as a first anti-reflection layer pattern 16A and a second silicon oxynitride layer pattern 15A, hereafter.

Referring to FIG. 1C, the first photoresist layer pattern 17 (refer to FIG. 1B) and the first anti-reflection layer pattern 16A (refer to FIG. 1B) are removed. The first photoresist layer pattern 17 (refer to FIG. 1B) and the first anti-reflection layer pattern 16A (refer to FIG. 1B) may be removed through a dry etch process, and the dry etch process may be an oxygen stripping process.

Subsequently, the first SOC layer 14 (refer to FIG. 1B) is etched using the second silicon oxynitride layer pattern 15A as an etch barrier. The etched first SOC layer 14 (refer to FIG. 1B) is referred to as a first SOC layer pattern 14A.

Referring to FIG. 1D, a first spacer-forming insulation layer 18, which is an insulation layer for forming a spacer, is formed over the second polysilicon layer 13, the first SOC layer pattern 14A, and the second silicon oxynitride layer pattern 15A. The first spacer-forming insulation layer 18 may be formed so that the sidewalls of the first SOC layer pattern 14A and the second silicon oxynitride layer pattern 15A are covered. To this end, a material having excellent step coverage may be used. For example, the first spacer-forming insulation layer 18 may be an ultra low temperature oxide (ULTO) layer.

Referring to FIG. 1E, a first spacer pattern 18A remaining on the sidewalls of the first SOC layer pattern 14A (refer to FIG. 1D) and the second silicon oxynitride layer pattern 15A (refer to FIG. 1D) is formed by etching the first spacer-forming insulation layer 18 (refer to FIG. 1D). Various etching processes (e.g., an isotropic etching) may be used to form the first spacer pattern 18A.

Subsequently, the first SOC layer pattern 14A (refer to FIG. 1D) and the second silicon oxynitride layer pattern 15A (refer to FIG. 1D) are removed. The second silicon oxynitride layer pattern 15A (refer to FIG. 1D) may be removed in the same etch process used for forming the first spacer pattern 18A. The first SOC layer pattern 14A (refer to FIG. 1D) may be removed through a dry etch process. For example, the dry etch process may be an oxygen stripping process.

As a result, only the first spacer pattern 18A remains over the second polysilicon layer 13.

Referring to FIG. 1F, a first line pattern 13A is formed by etching the second polysilicon layer 13 (refer to FIG. 1F) using the first spacer pattern 18A as an etch barrier. The first line pattern 13A is crossed by a second line pattern, which is formed later, and used as an etch mask during the formation of a mesh-type hard mask pattern for forming contact holes.

Referring to FIG. 1G, the first spacer pattern 18A (refer to FIG. 1F) is removed. Since the first spacer pattern 18A (refer to FIG. 1F) has an asymmetrical structure where the heights on the upper surface are different, if a lower layer is etched without removing the first spacer pattern 18A (refer to FIG. 1F), the asymmetrical structure of the first spacer pattern 18A (refer to FIG. 1F) may be transcribed and cause difficulties during a subsequent process for forming a contact hole, such as failing to completely open a contact hole.

Therefore, the asymmetrical structure may be prevented from being transcribed during a subsequent process of etching a lower layer by removing the first spacer pattern 18A (refer to FIG. 1F) in advance.

Referring to FIG. 1H, a second SOC layer 19, a third silicon oxynitride layer 20, and a second anti-reflection layer 21 are stacked over the first silicon oxynitride layer 12 and the first line pattern 13A. The second SOC layer 19 may be formed to have a thickness greater than the height of the first line pattern 13A. The second SOC layer 19 is a layer for forming the second line pattern. The second SOC layer 19 functions as a hard mask when a lower layer is etched along with the first line pattern 13A. The third silicon oxynitride layer 20 functions as a hard mask when the second SOC layer 19 is etched. The third silicon oxynitride layer 20 prevents reflection in an exposure process along with the second anti-reflection layer 21 when a second photoresist layer pattern 22 is formed. The second anti-reflection layer 21 functions not only as an anti-reflection layer during the exposure process when the second photoresist layer pattern 22 is formed, but also as a sacrificial layer in a subsequent process for forming a second spacer pattern.

Subsequently, the second photoresist layer pattern 22 is formed over the second anti-reflection layer 21. The second photoresist layer pattern 22 is a line type pattern. Particularly, the second photoresist layer pattern 22 may be formed in such a manner that a projection of it crosses the first line pattern 13A (i.e., if the second photoresist layer pattern 22 was in the same plane as the first line pattern 13A, they would cross). Also, the second photoresist layer pattern 22 is formed to have a space between its structures that takes into consideration a spacer pattern which will be formed later. The second photoresist layer pattern 22 may be formed to have pattern characteristics similar to the first photoresist layer pattern 17 (refer to FIG. 1A). That is, the second photoresist layer pattern 22 may have line-shaped structures with the same linewidth and space between as the photoresist layer pattern 17.

Referring to FIG. 1I, the second anti-reflection layer 21 (refer to FIG. 1H) is etched using the second photoresist layer pattern 22 as an etch barrier. The etched second anti-reflection layer 21 (refer to FIG. 1H) is referred to as a second anti-reflection layer pattern 21A.

The second anti-reflection layer pattern 21A and the second photoresist layer pattern 22 function as sacrificial layers for forming a spacer pattern, which is formed later.

Referring to FIG. 1J, a second spacer-forming insulation layer 23 is formed over the third silicon oxynitride layer 20, the second anti-reflection layer pattern 21A, and the second photoresist layer pattern 22. The second spacer-forming insulation layer 23 may be formed so that the sidewalls of the second anti-reflection layer pattern 21A and the second photoresist layer pattern 22 are covered. To this end, a material having excellent step coverage may be used. For example, the second spacer-forming insulation layer 23 may be an ultra low temperature oxide (ULTO) layer.

Referring to FIG. 1K, a second spacer pattern 23A remaining on the sidewalls of the second anti-reflection layer pattern 21A (refer to FIG. 1J) and the second photoresist layer pattern 22 (refer to FIG. 1J) is formed by etching the second spacer-forming insulation layer 23 (refer to FIG. 1J). Various etching processes (e.g., an isotropic etching) may be used to form the second spacer pattern 23A.

Subsequently, the second anti-reflection layer pattern 21A (refer to FIG. 1J) and the second photoresist layer pattern 22 (refer to FIG. 1J) are removed. The second anti-reflection layer pattern 21A (refer to FIG. 1J) and the second photoresist layer pattern 22 (refer to FIG. 1J) may be removed through a dry etch process. For example, the dry etch process may be an oxygen stripping process.

As a result, only the second spacer pattern 23A remains over the third silicon oxynitride layer 20.

Referring to FIG. 1L, the third silicon oxynitride layer 20 (refer to FIG. 1K) is etched using the second spacer pattern 23A as an etch barrier. The etched third silicon oxynitride layer 20 (refer to FIG. 1K) is referred to as a third silicon oxynitride layer pattern 20A, hereafter.

Referring to FIG. 1M, the second SOC layer 19 (refer to FIG. 1L) is etched using the second spacer pattern 23A and the third silicon oxynitride layer pattern 20A as etch barriers. The etched second SOC layer 19 (refer to FIG. 1L) is referred to as a second line pattern 19A, hereafter.

The second line pattern 19A crosses the first line pattern 13A, which remains and is partially exposed after etching the second SOC layer 19. The first line pattern 13A and the second line pattern 19A are used together as an etch mask when a mesh-type hard mask pattern for forming contact holes is formed.

The first line pattern 13A is not etched during the process for forming the second line pattern 19A due to its etch selectivity with respect to the second SOC layer 19.

Referring to FIG. 1N, the second spacer pattern 23A (refer to FIG. 1M) and the third silicon oxynitride layer pattern 20A (refer to FIG. 1M) are removed.

Since the second spacer pattern 23A (refer to FIG. 1M) has an asymmetrical structure where the heights on the upper surface are different, if a lower layer is etched without removing the second spacer pattern 23A (refer to FIG. 1M), the asymmetrical structure of the second spacer pattern 23A (refer to FIG. 1M) may be transcribed and cause difficulties during a subsequent process for forming a contact hole, such as failing to completely open a contact hole.

Therefore, it is possible to prevent the asymmetrical structure from being transcribed by removing the second spacer pattern 23A (refer to FIG. 1M) in advance.

Subsequently, the first silicon oxynitride layer 12 (refer to FIG. 1M) is etched using the first line pattern 13A and the second line pattern 19A as etch barriers. The etched first silicon oxynitride layer 12 (refer to FIG. 1M) is referred to as a first silicon oxynitride layer pattern 12A, hereafter.

Because the first line pattern 13A remains when the second line pattern 19A is formed and the two patterns cross, the first silicon oxynitride layer pattern 12A can be etched to form a mesh-type pattern, which has openings to expose parts of the amorphous carbon layer 11 below.

Referring to FIG. 1O, the first line pattern 13A (refer to FIG. 1N) and the second line pattern 19A are removed.

The first line pattern 13A (refer to FIG. 1N) and the second line pattern 19A may have different pattern heights, which may lead to etch non-uniformity. Therefore, if they are removed before further etching, etch non-uniformity may be prevented.

The amorphous carbon layer 11 (refer to FIG. 1N) is etched using the first silicon oxynitride layer pattern 12A as an etch barrier. The etched amorphous carbon layer 11 (refer to FIG. 1N) is referred to as an amorphous carbon layer pattern 11A, hereafter.

Referring to FIG. 1P, the first polysilicon layer 10 (refer to FIG. 1O) is etched using the first silicon oxynitride layer pattern 12A (refer to FIG. 1O) and the amorphous carbon layer pattern 11A (refer to FIG. 1O) as etch barriers. As a result a mesh-type hard mask pattern 10A is formed.

Subsequently, the first silicon oxynitride layer pattern 12A (refer to FIG. 1O) and the amorphous carbon layer pattern 11A (refer to FIG. 1O) are removed.

Subsequently, the etch target layer (not shown) is etched using the hard mask pattern 10A as an etch barrier so as to form a contact hole. In FIG. 1P, the hard mask pattern 10A is formed to be a square-shaped mesh-type pattern. However, the openings of the mesh may be formed in a variety of shapes. Moreover, it is also possible to form a circular contact hole using the square-shaped mesh-type hard mask pattern 10A to etch the etch target layer (not shown) due to a characteristic of the etch process that causes the edges to be smoothly rounded.

As described above, in the embodiment of the present invention, a Spacer Pattern Technology (SPT) process for forming a spacer pattern is performed twice to form line type patterns with crossing directions so as to form a mesh-type hard mask pattern. In particular, by removing a spacer pattern having an asymmetrical structure before a lower layer is etched, it is possible to prevent etch non-uniformity and pattern non-uniformity, which may be caused by the asymmetrical structure.

Also, the SPT process overcomes the limitation in resolution of the photoresist layer pattern.

While the present invention has been described with respect to the specific embodiments, it will be apparent to those skilled in the art that various changes and modifications may be made without departing from the spirit and scope of the invention as defined in the following claims.

What is claimed is:

1. A method for forming a contact hole of a semiconductor device, comprising:
forming a hard mask over an etch target layer;
forming a first line pattern over the hard mask;
forming a second line pattern over the hard mask and the first line pattern in a direction crossing the first line pattern;
forming a mesh-type hard mask pattern by etching the hard mask using the first and second line patterns as etch barriers; and
forming a contact hole by etching the etch target layer using the mesh-type hard mask pattern as an etch barrier.

2. The method of claim 1, wherein the hard mask has a stacked structure of a first polysilicon layer and a first silicon is oxynitride layer.

3. The method of claim 2, wherein the hard mask further comprises an oxide layer, an amorphous carbon layer, or a stacked layer of an oxide layer and an amorphous carbon layer between the first polysilicon layer and the first silicon oxynitride layer.

4. The method of claim 1, wherein the forming of the first line pattern comprises:
forming a first line mask over the hard mask;
forming a first sacrificial layer pattern over the first line mask;
forming a first spacer pattern on sidewalls of the first sacrificial layer pattern;
removing the first sacrificial layer pattern;
forming the first line pattern by etching the first line mask using the first spacer pattern as an etch barrier; and
removing the first spacer pattern.

5. The method of claim 4, wherein the forming of the first sacrificial layer pattern comprises:
forming a first sacrificial layer over the first line mask;
forming a second silicon oxynitride layer over the first sacrificial layer;
forming a first anti-reflection layer over the second silicon oxynitride layer;
forming a first photoresist layer pattern, having a line type pattern, over the first anti-reflection layer;
etching the first anti-reflection layer and the second silicon oxynitride layer by using the first photoresist layer pattern as an etch barrier;
removing the first photoresist layer pattern and the first anti-reflection layer; and
forming the first sacrificial layer pattern by etching the first sacrificial layer using the etched second silicon oxynitride layer as an etch barrier.

6. The method of claim 4, wherein the forming of the first spacer pattern comprises:
forming a spacer-forming insulation layer over the first line mask and the first sacrificial layer pattern; and
etching the spacer-forming insulation layer in such a manner that the spacer-forming insulation layer remains on sidewalls of the first sacrificial layer pattern.

7. The method of claim 4, wherein the first sacrificial layer pattern has an etch selectivity with respect to the first spacer pattern.

8. The method of claim 4, wherein the first spacer pattern has an etch selectivity with respect to the first line mask.

9. The method of claim 4, wherein the first line mask is a polysilicon layer.

10. The method of claim 4, wherein the first sacrificial layer pattern is a spin-on carbon (SOC) layer.

11. The method of claim 4, wherein the first spacer pattern is an ultra low temperature oxide (ULTO) layer.

12. The method of claim 1, wherein the forming of the second line pattern comprises:
forming a second line mask over the hard mask and the first line pattern;
forming a second sacrificial layer pattern over the second line mask;
forming a second spacer pattern on sidewalls of the second sacrificial layer pattern;
removing the second sacrificial layer pattern; and
forming the second line pattern by etching the second line mask using the second spacer pattern as an etch barrier.

13. The method of claim 12, wherein the second sacrificial layer pattern has a stacked structure of a second anti-reflection layer and a second photoresist layer pattern.

14. The method of claim 12, further comprising:
forming a third silicon oxynitride layer over the second line mask, before the forming of the second sacrificial layer pattern.

15. The method of claim 12, wherein the second line pattern is formed of a material having an etch selectivity with respect to the first line pattern.

16. The method of claim 12, wherein the second spacer pattern is formed of a material having an etch selectivity with respect to the second line mask.

17. The method of claim 12, wherein the second line mask is a spin-on carbon (SOC) layer.

18. The method of claim 12, wherein the second spacer pattern is an ultra low temperature oxide (ULTO) layer.

19. A method for forming a contact hole of a semiconductor device, comprising:
forming a hard mask over an etch target layer;
forming a first line mask over the hard mask;
forming a first spacer pattern over the first line mask;
forming a first line pattern by etching the first line mask using the first spacer pattern as an etch barrier;
removing the first spacer pattern;
forming a second line mask over the hard mask and the first line pattern;
forming a second spacer pattern over the second line mask in a direction crossing the first line pattern;
forming the second line pattern by etching the second line mask using the second spacer pattern as an etch barrier;
removing the second spacer pattern;
forming a mesh-type hard mask pattern by etching the hard mask; and
forming a contact hole by etching the etch target layer using the mesh-type hard mask pattern as an etch barrier.

20. The method of claim 19, further comprising:
forming a first hard mask between the hard mask and the first line mask;
forming a second hard mask between the first hard mask and the first line mask;
etching the second hard mask using the first and second line patterns as etch barriers; and
etching the first hard mask using the etched second hard mask as an etch barrier,
wherein the forming of the mesh-type hard mask pattern by etching the hard mask uses the etched first and second hard masks as etch barriers.
